(19) United States
(12) Patent Application Publication
(10) Pub. No.: US 2025/0327605 A1
(43) Pub. Date: Oct. 23, 2025

(54) TWO-PHASE COOLING SYSTEM AND COOLING METHOD

(71) Applicant: APALTEK CO., LTD., Shenzhen (CN)

(72) Inventors: Qineng XIAO, Dongguan (CN); Dagao ZHENG, Shenzhen (CN); Jianfeng LI, Shenzhen (CN); Jingyun HUANG, Shenzhen (CN); Jun-Chun QIU, Shenzhen (CN)

(21) Appl. No.: 18/811,770

(22) Filed: Aug. 22, 2024

(30) Foreign Application Priority Data
Apr. 18, 2024 (CN) 2024104706440

(51) Int. Cl. F25B 41/42

(52) U.S. Cl. CPC F25B 41/42; F25B 2500/18

(57) ABSTRACT

A two-phase cooling system includes a circulation device, a first cooling device and a second cooling device. The circulation device includes a liquid supply main path and a liquid supply branch path. The first cooling device is disposed on the liquid supply main path. The second cooling device is disposed with a phase change material and disposed on the liquid supply branch path. The two-phase cooling system is configured with a first operation mode and a second operation mode. The first cooling device is connected with the second cooling device in parallel when the two-phase cooling system is in the first operation mode. The first cooling device is serially connected with the second cooling device when the two-phase cooling system is in the second operation mode.

### BACKGROUND

### Technical Field

The disclosure relates to a field of a cooling device technology, particularly to a two-phase cooling system and a cooling method.

### Related Art

In the field of modern server applications, due to the increasing popularity of high-power and high (large) heat flux electronic equipment, traditional single-phase liquid cooling technology faces challenges and is difficult to meet the requirements of large heat flux.

In the prior art, a pump-driven two-phase flow cooling system with greater cooling capacity is often used to dissipate heat from servers with high heat flux. Although the pump-driven two-phase flow cooling system performs well under high thermal loading, its cooling performance is obviously excessive when the server is operated with a low power, and this results in serious waste of energy.

In view of this, the inventors have devoted themselves to the above-mentioned prior art, researched intensively and cooperated with the application of science to try to solve the above-mentioned problems. Finally, the invention which is reasonable and effective to overcome the above drawbacks is provided.

### SUMMARY

An object of the disclosure is to provide a cooling device technology, particularly to a two-phase cooling system and a cooling method so as to overcome the problems of poor energy efficiency and waste in the structure of the two-phase cooling system of prior-art.

To accomplish the above object, the disclosure provides a two-phase cooling system, which includes a circulation device, a first cooling device and a second cooling device. The circulation device includes a liquid supply main path and a liquid supply branch path. The first cooling device is disposed on the liquid supply main path. The second cooling device is disposed with a phase change material and disposed on the liquid supply branch path. The two-phase cooling system is configured with a first operation mode and a second operation mode. The first cooling device is connected with the second cooling device in parallel when the two-phase cooling system is in the first operation mode. The first cooling device is serially connected with the second cooling device when the two-phase cooling system is in the second operation mode.

Optionally, the circulation device includes a circulating pump, an evaporation cooling plate and a liquid storage tank, the liquid supply main path includes a first main path and a second main path, the liquid storage tank, the first main path, the evaporation cooling plate and the second main path are connected with each other to define a loop, the circulation pump is disposed on the first main path, and the first cooling device is disposed on the second main path.

Optionally, the liquid supply branch path includes a first branch path and a second branch path, the second cooling device is disposed with a liquid inlet and a liquid outlet, an end of the first branch path is connected to the liquid inlet, an end of the first branch path, which is away from the liquid inlet, is connected to the first main path, an end of the second branch path is connected to the liquid outlet, and an end of the second branch path, which is away from the liquid outlet, is connected to the second main path.

Optionally, the first branch path is disposed with a first valve, the liquid supply branch path further includes a third branch path, an end of the third branch path is connected to the first branch path at a first joint located between the first valve and the liquid inlet, an end of the third branch path away from the first joint is connected to the second main path at a second joint located between the first cooling device and the liquid storage tank, and the third branch path is disposed with a third valve located between the first joint and the second joint.

Optionally, the second branch path is disposed with a second valve, the liquid supply branch path further includes a fourth branch path, an end of the fourth branch path is connected to the second branch path at a third joint located between the liquid outlet and the second valve, an end of the fourth branch path away from the third joint is connected to the second main path at a fourth joint located between the third joint and the first cooling device, and the fourth branch path is disposed with a fourth valve disposed between the third joint and the fourth joint.

Optionally, multiple evaporation cooling plates are provided, the circulation device further includes a liquid distributor and a liquid collector, the liquid distributor is connected to the first main path for distributing the refrigerant to the multiple evaporation cooling plates, and the liquid collector is connected to the second main path for collecting the refrigerant in the multiple evaporation cooling plates and returning to the second main path.

Optionally, the second cooling device further includes multiple flowing layers and multiple energy storage layers, and the flowing layers and the energy storage layers are alternately stacked along a height direction.

Optionally, the flowing layer includes a flowing layer body and multiple refrigerant passages, the flowing layer body is defined with a length direction and a width direction, which are perpendicular to each other, the multiple refrigerant passages are extended along the length direction of the flowing layer body, and the refrigerant passages are disposed in parallel along the width direction of the flowing layer body.

Optionally, the energy storage layer includes multiple independent storage portions for storing the phase change material.

The disclosure additionally provides a cooling method based on the aforementioned two-phase cooling system, wherein the first operation mode includes a first regular operation and a first high-loading operation. The second operation mode includes a second regular operation and a second high-loading operation. The cooling method includes: detecting an instant operating operation of the two-phase cooling system; the circulation pump and the first cooling device are operated with only opening the first valve when the two-phase cooling system is in the first regular operation, the circulation pump and the first cooling device are operated with closing the first valve and opening the third valve when the two-phase cooling system is in the first high-loading operation, the circulation pump and the first cooling device are operated with closing the first valve and the second valve and opening the third valve and the fourth valve when the two-phase cooling system is in the second high-loading operation.

In comparison with the related art, the disclosure has the following functions: the disclosure provides a two-phase cooling system and a cooling method. The two-phase cooling system includes a circulation device, a first cooling device and a second cooling device. The second cooling device is disposed with a phase change material. The first operation mode and the second operation mode make the two-phase cooling system in a low-loading status not only perform regular cooling, but also store excessive cooling store excessive cooling capacity by the phase material in the second cooling device 13. When the two-phase cooling system is in a high loading status, the phase change material in the second cooling device releases the stored cooling capacity before. The disposition of the phase change material, the first operation mode and the second operation mode effectively manage storage and release of cooling capacity, obviously reduces energy consumption of the two-phase cooling system 10, and improves energy efficiency of the two-phase cooling system.

### BRIEF DESCRIPTION OF THE DRAWINGS

FIG. 1 is a schematic view of the principle of the two-phase cooling system of the disclosure;

FIG. 2 is a schematic view of the principle of the two-phase cooling system of the disclosure;

FIG. 3 is a schematic view of the principle of a variation of the two-phase cooling system of the disclosure; and

FIG. 4 is a partially structural perspective schematic view of a partial structure of the second cooling device of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

In the description of the disclosure, it is noted that the terms indicating directions or positional relationship such as “central”, “longitudinal”, “transverse”, “upper”, “lower”, “front”, “rear”, “left”, “right”, “perpendicular”, “horizontal”, top”, “bottom”, “inner and “outer”, are based upon the directions or positional relationship shown in the figures. They are used to depict the disclosure and simplify the description but not to express or imply that the indicated devices or elements must have a specific direction or be constructed or operated in a specific direction. Thus, they should not be construed as limitations of the disclosure. In addition, the terms used in the description, such as “first” and “second”, are used for depiction, but cannot be understood to be a relative expression or hint or imply the amount of a technical feature indicated. Those technical features limited by “first” or “second” may express or imply that one or more features are included. In the description of the disclosure, unless expressively indicated, the term “multiple” means two or more.

In the description of the disclosure, it should be noted that, unless otherwise clearly stated and limited, the terms “installation” and “connection” should be understood in a broad sense. For example, it can be a fixed connection, a detachable connection or an integral connection; it can be a mechanical connection or an electrical connection; it can be a direct connection or an indirect connection through an intermediate medium; and it can be an internal communication between two components. For those of ordinary skill in the art, the specific meanings of the above terms in this disclosure can be understood on a case-by-case basis.

### System Embodiment 1

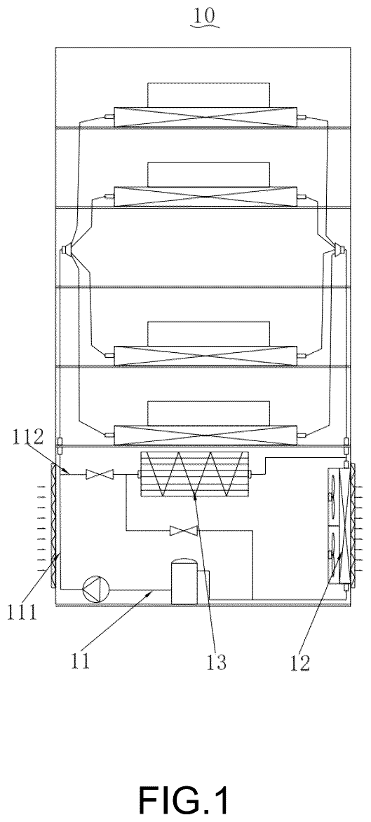

Please refer to FIG. 1. The disclosure provides a two-phase cooling system 10, which includes a circulation device 11, a first cooling device 12 and a second cooling device 13. The circulation device 11 includes a liquid supply main path 111 (the main path means a trunk of a path) and a liquid supply branch path 112 (the branch path means a branch of a path). In detail, the liquid supply main path 111 is used for a cooling process of a main flow (the inner circulation of the refrigerant in the liquid supply main path 111 is the main flow). The liquid supply branch path 112 is used for connecting the second cooling device 13 with a phase change material to make the second cooling device 13 optionally perform absorption or release of heat according to the requirements. The first cooling device 12 is disposed on the liquid supply main path 111 of the circulation device 11. The first cooling device 12 is responsible for performing the main cooling function to dissipate the heat carried by the refrigerant into the environment to implement the basic cooling need of the two-phase cooling system 10. The second cooling device 13 is disposed with a phase change material and disposed on the liquid supply branch path 112. In detail, the second cooling device 13 is used to store (absorb) or release heat under specific conditions so as to improve the heat management efficiency of the system. The phase-change material changes its phase when absorbing excessive heat to store heat and releases the heat when needs increase.

The two-phase cooling system 10 has two operating modes: a first operation mode and a second operation mode. The first cooling device 12 is connected with the second cooling device 13 in parallel when the two-phase cooling system 10 is in the first operation mode. In detail, in the first operation mode, the first cooling device 12 and the second cooling device 13 are disposed in parallel, the second cooling device 13 stores excessive cooling capacity when the load is low, and the cooling needs of the main flow (the inner circulation of the refrigerant in the liquid supply main path 111 is the main flow) is satisfied by the first cooling device 12; when the load is high, the first cooling device 12 and the second cooling device 13, which are disposed in parallel, may simultaneously perform split cooling to the coolant. The first cooling device 12 is serially connected with the second cooling device 13 when the two-phase cooling system 10 is in the second operation mode. In detail, in the second operation mode, the first cooling device 12 and the second cooling device 13 are disposed in series, when the load is high, the refrigerant in the two-phase cooling system 10 is preliminarily cooled by the first cooling device 12 first, then cooled further by the second cooling device 13, and simultaneously releases the stored cooling capacity during low loading to correspond to the increased heat load.

By way of the phase change material, the first operation mode and the second operation mode, the two-phase cooling system 10 can automatically adjust its cooling strategy according to operations so as to obviously reduce energy consumption and increase the overall energy efficiency of the two-way cooling system 10. It effectively solves the problems of overmuch cooling performance and energy waste of a prior-art pump-driven two-phase flow cooling system operating under the condition of low power.

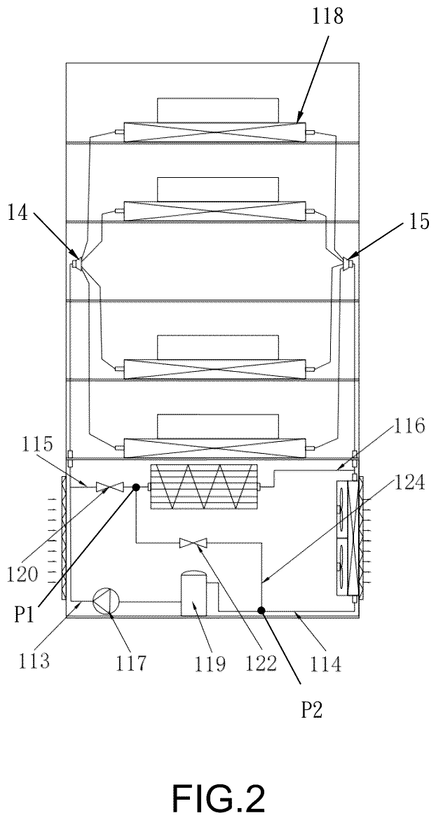

Please refer to FIGS. 1 and 2. In some embodiments, the circulation device 11 includes a circulating pump 117, an evaporation cooling plate 118 and a liquid storage tank 119. The liquid supply main path 111 includes a first main path 113 and a second main path 114. The liquid storage tank 119, the first main path 113, the evaporation cooling plate 118 and the second main path 114 are connected with each other to define a loop to keep continuous circulation of the refrigerant. The circulation pump 117 is disposed on the first main path 113 to push the refrigerant to flow from the liquid storage tank 119 to the evaporation cooling plate 118 via the first main path 113 and to complete cooling and flowing back. The first cooling device 12 is disposed on the second main path 114 and between the evaporation cooling plate 118 and the liquid storage tank 119 to guarantee that the hot refrigerant flowing from the evaporation cooling plate 118 can be cooled before coming back to the liquid storage tank 119.

In some embodiments, the liquid supply branch path 112 includes a first branch path 115 and a second branch path 116. The second cooling device 13 is disposed with a liquid inlet and a liquid outlet (all unlabeled) to make the refrigerant perform effective heat exchange by passing the second cooling device 13. An end of the first branch path 115 is connected to the liquid inlet and an end of the first branch path 115, which is away from the liquid inlet, is connected to the first main path 113 so as to make the refrigerant split from the first main path 113 into the second cooling device 13. An end of the second branch path 116 is connected to the liquid outlet and an end of the second branch path 116, which is away from the liquid outlet, is connected to the second main path 114 so as to make the refrigerant treated by the second cooling device 13 able to re-enter the liquid supply main path 111 to integrate into the main circulation to further improve the cooling efficiency of the whole system.

In detail, by way of the second cooling device 13, the first branch path 115 and the second branch path 116, the second cooling device 13 may flexibly perform heat management according to system requirements. When the load is low, the second cooling device 13 may serve as an energy storage unit to store cooling capacity and reduce energy consumption of the system. When the load is high, the second cooling device 13 may rapidly release the stored cooling capacity to provide additional cooling ability so as to keep high-performance operation of the system. In addition, by way of the liquid supply branch path 112 which is independently disposed, the second cooling device 13 may independently operate without affecting the main circulation to increase adaptiveness and responding speed of the system.

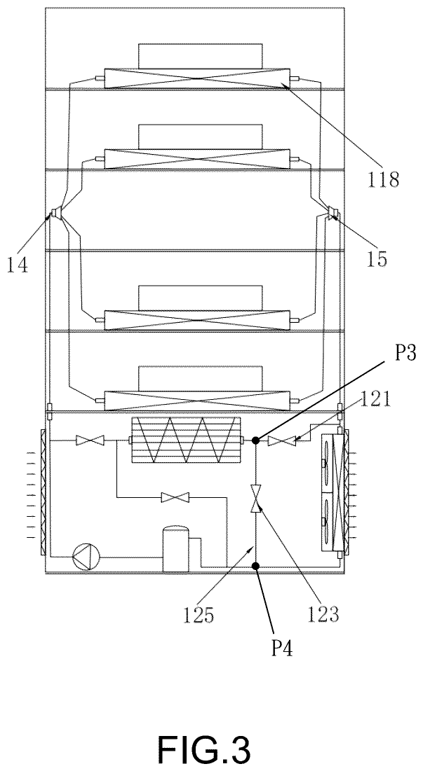

Please refer to FIGS. 1-3. In some embodiments, the first branch path 115 is disposed with a first valve 120 for closing and controlling the flowing amount of the refrigerant flowing to the second cooling device 13 so as to adjust its cooling performance and heat storage ability. The liquid supply branch path 112 further includes a third branch path 124. An end of the third branch path 124 and the first branch path 115 are connected to be a first joint P1 located between the first valve 120 and the liquid inlet. In detail, the two-phase cooling system 10 is disposed with a third branch path 124. An end of the third branch path 124 is connected to the first joint P1 of the first branch path 115 between the first valve 120 and the liquid inlet. An end of the third branch path 124, which is away from the first joint P1, is connected to the second main path 114 at a second joint P2 located between the first cooling device 12 and the liquid storage tank 119 to allow the refrigerant to split on the second main path 114 before entering the first cooling device 12. A part of the refrigerant may directly enter the first cooling device 12 to perform heat treatment, and another part of the refrigerant may bypass the first cooling device 12 to enter the second cooling device 13 via the second branch path 116. The third branch path 124 is disposed with a third valve 122 for controlling the refrigerant to flow in the third branch path 124. After the refrigerant passes the second branch path 116 to enter the second cooling device 13, an additional heat exchange treatment may be performed, especially when the two-phase cooling system 10 is in a high-loading status, the second cooling device 13 provides additional cooling ability. The refrigerant treated by the second cooling device 13 returns to the second main path 114 via the third branch path 124 and may directly enter the liquid storage tank 119 instead of re-passing the first cooling device 12. This reduces the circulation path of the refrigerant, improves system efficiency and adjusts cooling performance according to different heat loading requirements.

Please refer to FIGS. 1-3. In some embodiments, the evaporation cooling plate 118 is configured to be multiple. The multiple evaporation cooling plates 118 are in contact with unpassed loads to maximize the capturing and removing efficiency of heat. The circulation device 11 further includes a liquid distributor 14 and a liquid collector 15. The liquid distributor 14 is connected to the first main path 113 for distributing the refrigerant to multiple evaporation cooling plates 118. In detail, the liquid distributor 14 can evenly distribute the refrigerant from the circulation pump 117 to each evaporation cooling plate 118 to guarantee that each evaporation cooling plate 118 can obtain sufficient flowing amount of the refrigerant to meet its cooling need. The liquid collector 15 is connected to the second main path 114 for collecting the refrigerant in the multiple evaporation cooling plates 118 and returning to the second main path 114. The liquid collector 15 can collect the refrigerant in each evaporation cooling plate 118 and then integratedly flow back to the second main path 114.

The multiple evaporation cooling plates 118, the liquid distributor 14 and the liquid collector 15 make the two-phase cooling system 10 able to be adapted to different heat loads and distributions to help to keep continuously flowing of the refrigerant in the system, improve the circulation efficiency and guarantee effective removing of heat so as to further increase the whole cooling performance, reduce energy consumption and improve stability and reliability of the system.

Please refer to FIGS. 1-4. In some embodiments, the second cooling device 13 further includes multiple flowing layers 131 and multiple energy storage layers 132. Each flowing layer 131 and each energy storage layer 132 are adjacent and superposed. In detail, the flowing layers 131 and the energy storage layers 132 are alternately stacked, the flowing layers 131 are used for flowing and heat exchange of the refrigerant, and the energy storage layers 132 are used for storage and release of cooling capacity, so as to implement the composite cooling function of the two-phase cooling system 10. The flowing layers 131 and energy storage layers 132 may store excessive cooling capacity by the energy storage layers 132 while the first cooling device 12 is executing the regular cooling function, so as to rapidly release the cooling capacity when the two-phase cooling system 10 needs it. That is, when the system loading suddenly increases, the energy storage layers 132 may provide additional cooling capacity to help to keep temperature balance of the system.

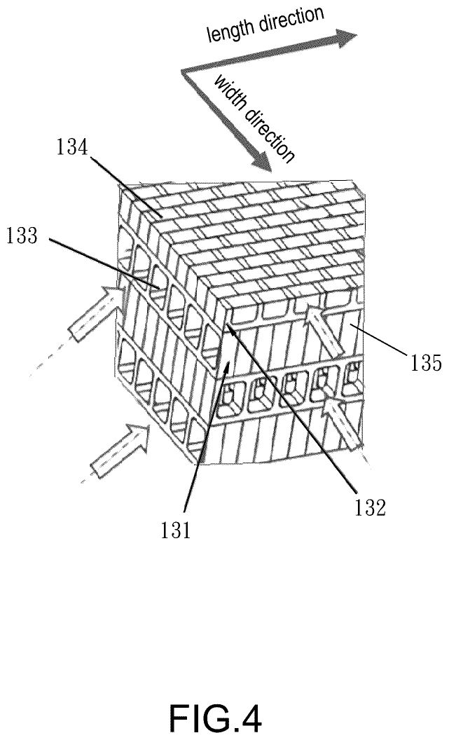

Please refer to FIGS. 1-4. In some embodiments, the flowing layer 131 includes a flowing layer body 135 and multiple refrigerant passages 133. All the multiple refrigerant passages 133 extend along the length direction of the flowing layer body 135 (as shown in FIG. 4), and refrigerant passages 133 are disposed in parallel along the width direction of the flowing layer body 135 (as shown in FIG. 4). In detail, the refrigerant may freely flow in the whole second cooling device 13. The refrigerant passages 133 are disposed adjacently to add the flowing area and the contact surface of the refrigerant so as to increase heat exchange ability. The energy storage layer 132 includes multiple independent storage portions 134 for storing the phase change material to make the first cooling device 12 able to rapidly release or absorb cooling capacity by the phase change material in the energy storage layer 132 when needed. The phase change material makes the energy storage layer 132 able to accumulate cooling capacity when the system heat loading is low and rapidly release cooling refrigerant when the system heat loading increases, so as to help to keep temperature stability of the system. The phase change material may be paraffin, fatty acids, alcohols and metal salts, and paraffin is preferable.

### System Embodiment 2

Please refer to FIGS. 1-3. To further enhance cooling ability of the two-phase cooling system 10, the two-phase cooling system 10 provided by the system embodiment 1 is added with a fourth branch path 125 and a fourth valve 123.

The second branch path 116 is disposed with a second valve 121 for controlling the refrigerant to flow from the second cooling device 13 to the second main path 114 or controlling the refrigerant to flow from the second main path 114 to the second cooling device. The liquid supply branch path 112 further includes a fourth branch path 125. An end of the fourth branch path 125 and the second branch path 116 are connected to be a third joint P3 located between the liquid outlet and the second valve 121. An end of the fourth branch path 125, which is away from the third joint P3, is connected to the second main path 114 at a fourth joint P4 located between the third joint P3 and the first cooling device 12. In detail, the fourth branch path 125 allows the refrigerant to be preliminarily cooled by the first cooling device 12 first, then flow to the second cooling device 13 to further perform heat treatment. The fourth branch path 125 is disposed with a fourth valve 123 for controlling the refrigerant to pass the first cooling device 12 first and then flow to the second cooling device 13. In other words, the fourth valve 123 is disposed between the third joint P3 and the fourth joint P4. The fourth valve 123 allows the refrigerant to pass the first cooling device 12 first, and then flow to the second cooling device 13, after the heat exchange treatments by the first cooling device 12 and the second cooling device 13, flow to the second main path 114, and finally flow into the liquid storage tank 119.

### Method Embodiment 1

The method embodiment 1 of the disclosure is based upon the two-phase cooling system 10 of the system embodiment 1, which provides a cooling method:
When the two-phase cooling system 10 of the system embodiment 1 is in the first regular operation, the refrigerant is stored in the liquid storage tank 119;
S11, operating the circulation pump 117, extracting the refrigerant from the liquid storage tank 119 and pushing to the first main path 113;
S12, opening the first valve 120 to make the refrigerant separately flow to the second cooling device 13 and the liquid distributor 14.

In detail, part of the refrigerant passes the first valve 120 to enter the second cooling device 13, the second cooling device 13 is filled with paraffin, so in the second cooling device 13, the refrigerant takes heat of the paraffin by the contact with the filled paraffin, and the cooling capacity is stored in the second cooling device 13 to result in lowering the temperature of the paraffin with a change from liquid to solid.

The other part passes the liquid distributor 14 to enter the evaporation cooling plate 118 to take heat of the heat source through the refrigerant. Finally, the refrigerant flows into the first cooling device 12. Heat of the refrigerant in the first cooling device 12 is taken by a fan (unlabeled, the first cooling device 12 includes a fan). Meanwhile, the fan uses a vent (unlabeled) to take heat generated from the working two-phase cooling system 10, and heat in a box (unlabeled) of the two-phase cooling system 10 is also be lowered.

When the two-phase cooling system 10 of the system embodiment 1 is in the first high-loading operation, the split refrigerant cannot satisfy the cooling capacity of the evaporation cooling plate 118;
S13, closing the first valve 120 and opening the third valve 122 to make the refrigerant redistributed.

All the flowing amount of the refrigerant brought by the circulation pump 117 passes the liquid supply main path 111 to enter the liquid distributor 14 and each evaporation cooling plate 118, and is then collected by the liquid collector 15. Part of the refrigerant passes the second branch path 116 to enter the second cooling device 13. Heat of the refrigerant is taken by the paraffin in the second cooling device 13. The paraffin changes from solid to liquid, i.e., the second cooling device 13 releases cooling capacity. The other part passes the second main path 114 to enter the first cooling device 12. The refrigerant entering the second cooling device 13 and entering the first cooling device 12 will be finally collected into the liquid storage tank 119.

This method effectively adjusts the cooling performance of the two-phase cooling system 10 under different heat loading conditions, effectively manages storage and release of cooling capacity, obviously reduces energy consumption of the two-phase cooling system 10, and improves energy efficiency of the two-phase cooling system 10. Under the regular operation and the high-loading operation, different valve dispositions allow the system to flexibly respond to temperature changes. This not only increases cooling efficiency, but also guarantees performance and reliability of the device under various operations.

### Method Embodiment 2

The method embodiment 2 of the disclosure is based upon the two-phase cooling system 10 of the system embodiment 2, which provides another cooling method:
When the two-phase cooling system 10 of the system embodiment 2 is in the first regular operation;
S21, operating the circulation pump 117, extracting the refrigerant from the liquid storage tank 119 and pushing to the first main path 113;
S22, opening the first valve 120 and the second valve 121 to make the refrigerant separately flow to different paths;
S23, closing the third valve 122 and the fourth valve 123 to prevent the refrigerant from flowing to a non-predetermined path.

The refrigerant is stored in the liquid storage tank 119. When the circulation pump 117 is operating, the refrigerant in the liquid storage tank 119 is taken out, and the refrigerant splits in the first main path 113. A part passes the first valve 120 to enter the second cooling device 13, the second cooling device 13 is filled with paraffin, so part of heat of the paraffin in the second cooling device 13 will be taken by the refrigerant to store cooling capacity in the second cooling device 13. The other part of the refrigerant passes the liquid distributor 14 to enter the evaporation cooling plate 118 to take heat of the heat source through the refrigerant. Finally, the refrigerant passes the second branch path 116 and the second main path 114 to flow into the first cooling device 12. Heat of the refrigerant in the first cooling device 12 is taken by a fan. Meanwhile, the fan also takes part of heat generated from the working two-phase cooling system 10.

When the two-phase cooling system 10 of the system embodiment 2 is in the second high-loading operation, the split refrigerant cannot satisfy the cooling capacity of the evaporation cooling plate 118.
S24, closing the first valve 120 and the second valve 121 to block the original split paths of the refrigerant.
S25, opening the third valve 122 and the fourth valve 123 to re-arrange the flowing direction of the refrigerant;
All the flowing amount brought by the circulation pump 117 passes the liquid distributor 14 to enter each evaporation cooling plate 118. The refrigerant is collected by the liquid collector 15 and all the refrigerant enters the first cooling device 12 to make heat exchange with air. Part of the refrigerant is split to flow into the second cooling device 13. Heat of the refrigerant is taken by the paraffin in the second cooling device 13. The paraffin changes from solid to liquid, i.e., the second cooling device 13 releases cooling capacity. Finally, the refrigerant is collected to enter the liquid storage tank 119.

The difference between method embodiment 1 and method embodiment 2 is that under the high-loading operation, after the refrigerant of method embodiment 1 passes the liquid collector 15, the refrigerant is split to separately enter the second cooling device 13 and the first cooling device 12. In the method embodiment 2 under the high-loading operation, after the refrigerant passes the liquid collector 15, all enters the first cooling device 12 first, then part of the refrigerant is split to enter the second cooling device 13, and finally collected to enter the liquid storage tank 119 to complete the circulation.

This method effectively adjusts the cooling performance of the two-phase cooling system 10 under different heat loading conditions, effectively manages storage and release of cooling capacity, obviously reduces energy consumption of the two-phase cooling system 10, and improves energy efficiency of the two-phase cooling system 10. Under the regular operation and the high-loading operation, different valve dispositions allow the system to flexibly respond to temperature changes. This not only increases cooling efficiency, but also guarantees performance and reliability of the device under various operations.

In sum, the disclosure provides a two-phase cooling system and a cooling method, which includes a circulation device 11, the circulation device 11 includes a liquid supply main path 111 and a liquid supply branch path 112; a first cooling device 12, the first cooling device 12 is disposed on the liquid supply main path 111 of the circulation device 11; a second cooling device 13, the second cooling device 13 is disposed with a phase change material and disposed on the liquid supply branch path 112. The two-phase cooling system 10 is configured with a first operation mode and a second operation mode. The first cooling device is connected with the second cooling device 13 in parallel when the two-phase cooling system 10 is in the first operation mode. The first cooling device 12 is serially connected with the second cooling device 13 when the two-phase cooling system 10 is in the second operation mode. In other words, the two-phase cooling system 10 includes a circulation device 11, a first cooling device 12 and a second cooling device 13. The second cooling device 13 is disposed with a phase change material. The first operation mode and the second operation mode make the two-phase cooling system 10 in a low-loading status not only perform regular cooling, but also store excessive cooling store excessive cooling capacity by the phase material in the second cooling device 13. When the two-phase cooling system 10 is in a high loading status, the phase change material in the second cooling device 13 releases the stored cooling capacity before. The disposition of the phase change material, the first operation mode and the second operation mode effectively manage storage and release of cooling capacity, obviously reduces energy consumption of the two-phase cooling system 10, and improves energy efficiency of the two-phase cooling system 10.

While this disclosure has been described by means of specific embodiments, numerous modifications and variations could be made thereto by those skilled in the art without departing from the scope and spirit of this disclosure set forth in the claims.

What is claimed is:

1. A two-phase cooling system comprising:
a circulation device, comprising a liquid supply main path and a liquid supply branch path;
a first cooling device, disposed on the liquid supply main path; and
a second cooling device, disposed with a phase change material, and disposed on the liquid supply branch path;
wherein the two-phase cooling system is configured with a first operation mode and a second operation mode, the first cooling device is connected with the second cooling device in parallel when the two-phase cooling system is in the first operation mode, and the first cooling device is serially connected with the second cooling device when the two-phase cooling system is in the second operation mode.

2. The two-phase cooling system of claim 1, wherein the circulation device comprises a circulating pump, an evaporation cooling plate and a liquid storage tank, the liquid supply main path comprises a first main path and a second main path, the liquid storage tank, the first main path, the evaporation cooling plate and the second main path are connected with each other to define a loop, the circulation pump is disposed on the first main path, and the first cooling device is disposed on the second main path.

3. The two-phase cooling system of claim 2, wherein the liquid supply branch path comprises a first branch path and a second branch path, the second cooling device is disposed with a liquid inlet and a liquid outlet, an end of the first branch path is connected to the liquid inlet, an end of the first branch path, which is away from the liquid inlet, is connected to the first main path, an end of the second branch path is connected to the liquid outlet, and an end of the second branch path, which is away from the liquid outlet, is connected to the second main path.

4. The two-phase cooling system of claim 3, wherein the first branch path is disposed with a first valve, the liquid supply branch path further comprises a third branch path, an end of the third branch path and the first branch path are connected to be a first joint located between the first valve and the liquid inlet, an end of the third branch path, which is away from the first joint, is connected to the second main path at a second joint located between the first cooling device and the liquid storage tank, and the third branch path is disposed with a third valve located between the first joint and the second joint.

5. The two-phase cooling system of claim 4, wherein the second branch path is disposed with a second valve, the liquid supply branch path further comprises a fourth branch path, an end of the fourth branch path and the second branch path are connected to be a third joint located between the liquid outlet and the second valve, an end of the fourth branch path, which is away from the third joint, is connected to the second main path at a fourth joint located between the third joint and the first cooling device, and the fourth branch path is disposed with a fourth valve disposed between the third joint and the fourth joint.

6. The two-phase cooling system of claim 2, wherein the evaporation cooling plate is configured to be multiple, the circulation device further comprises a liquid distributor and a liquid collector, the liquid distributor is connected to the first main path for distributing the refrigerant to the multiple evaporation cooling plates, and the liquid collector is connected to the second main path for collecting the refrigerant in the multiple evaporation cooling plates and returning to the second main path.

7. The two-phase cooling system of claim 1, wherein the second cooling device further comprises multiple flowing layers and multiple energy storage layers, and the flowing layers and the energy storage layers are alternately stacked along a height direction.

8. The two-phase cooling system of claim 7, wherein the flowing layer comprises a flowing layer body and multiple refrigerant passages, the flowing layer body is defined with a length direction and a width direction, which are perpendicular to each other, the multiple refrigerant passages are extended along the length direction of the flowing layer body, and the refrigerant passages are disposed in parallel along the width direction of the flowing layer body.

9. The two-phase cooling system of claim 7, wherein the energy storage layer comprises multiple independent storage portions for storing the phase change material.

10. The two-phase cooling system of claim 2, wherein the second cooling device further comprises multiple flowing layers and multiple energy storage layers, and the flowing layers and the energy storage layers are alternately stacked along a height direction.

11. The two-phase cooling system of claim 10, wherein the flowing layer comprises a flowing layer body and multiple refrigerant passages, the flowing layer body is defined with a length direction and a width direction, which are perpendicular to each other, the multiple refrigerant passages are extended along the length direction of the flowing layer body, and the refrigerant passages are disposed in parallel along the width direction of the flowing layer body.

12. The two-phase cooling system of claim 10, wherein the energy storage layer comprises multiple independent storage portions for storing the phase change material.

13. The two-phase cooling system of claim 3, wherein the second cooling device further comprises multiple flowing layers and multiple energy storage layers, and the flowing layers and the energy storage layers are alternately stacked along a height direction.

14. The two-phase cooling system of claim 13, wherein the flowing layer comprises a flowing layer body and multiple refrigerant passages, the flowing layer body is defined with a length direction and a width direction, which are perpendicular to each other, the multiple refrigerant passages are extended along the length direction of the flowing layer body, and the refrigerant passages are disposed in parallel along the width direction of the flowing layer body.

15. The two-phase cooling system of claim 13, wherein the energy storage layer comprises multiple independent storage portions for storing the phase change material.

16. The two-phase cooling system of claim 4, wherein the second cooling device further comprises multiple flowing layers and multiple energy storage layers, and the flowing layers and the energy storage layers are alternately stacked along a height direction.

17. The two-phase cooling system of claim 16, wherein the flowing layer comprises a flowing layer body and multiple refrigerant passages, the flowing layer body is defined with a length direction and a width direction, which are perpendicular to each other, the multiple refrigerant passages are extended along the length direction of the flowing layer body, and the refrigerant passages are disposed in parallel along the width direction of the flowing layer body.

18. The two-phase cooling system of claim 16, wherein the energy storage layer comprises multiple independent storage portions for storing the phase change material.

19. The two-phase cooling system of claim 5, wherein the second cooling device further comprises multiple flowing layers and multiple energy storage layers, and the flowing layers and the energy storage layers are alternately stacked along a height direction.

20. The two-phase cooling system of claim 19, wherein the flowing layer comprises a flowing layer body and multiple refrigerant passages, the flowing layer body is defined with a length direction and a width direction, which are perpendicular to each other, the multiple refrigerant passages are extended along the length direction of the flowing layer body, and the refrigerant passages are disposed in parallel along the width direction of the flowing layer body.

21. The two-phase cooling system of claim 19, wherein the energy storage layer comprises multiple independent storage portions for storing the phase change material.

22. The two-phase cooling system of claim 6, wherein the second cooling device further comprises multiple flowing layers and multiple energy storage layers, and the flowing layers and the energy storage layers are alternately stacked along a height direction.

23. The two-phase cooling system of claim 22, wherein the flowing layer comprises a flowing layer body and multiple refrigerant passages, the flowing layer body is defined with a length direction and a width direction, which are perpendicular to each other, the multiple refrigerant passages are extended along the length direction of the flowing layer body, and the refrigerant passages are disposed in parallel along the width direction of the flowing layer body.

24. The two-phase cooling system of claim 22, wherein the energy storage layer comprises multiple independent storage portions for storing the phase change material.

25. A cooling method as claimed in the two-phase cooling system of claim 5, wherein the first operation mode comprises a first regular operation and a first high-loading operation, the second operation mode comprises a second regular operation and a second high-loading operation, the cooling method comprises: detecting an instant operating operation of the two-phase cooling system; the circulation pump and the first cooling device are operated with only opening the first valve when the two-phase cooling system is in the first regular operation, the circulation pump and the first cooling device are operated with closing the first valve and opening the third valve when the two-phase cooling system is in the first high-loading operation, the circulation pump and the first cooling device are operated with closing the first valve and the second valve and opening the third valve and the fourth valve when the two-phase cooling system is in the second high-loading operation.
